(19) United States
(12) Patent Application Publication
(10) Pub. No.: US 2015/0291417 A1
(43) Pub. Date: Oct. 15, 2015

(54) DEVICE PACKAGING METHOD AND DEVICE PACKAGE USING THE SAME

(71) Applicant: Korea Advanced Institute of Science & Technology, Daejeon (KR)

(72) Inventors: Jun Bo YOON, Daejeon (KR); Chang Hoon Han, Daejeon (KR); Yong Hoon Yoon, Daejeon (KR); Jae Shin Lee, Daejeon (KR)

(73) Assignee: Korea Advanced Institute of Science & Technology, Daejeon (KR)

(21) Appl. No.: 14/612,554

(22) Filed: Feb. 3, 2015

(30) Foreign Application Priority Data
Apr. 14, 2014 (KR) 10-2014-0044469

(51) Int. Cl. B81C 1/00; B81B 7/00

(52) U.S. Cl. CPC B81C 1/0038; B81C 1/00333; B81B 7/0077

(57) ABSTRACT

A device packaging method and a device package using the same may be provided. The device packaging method includes forming a package sacrificial layer by applying a first material on a substrate on which a device has been formed; forming a package cap by applying a second material on the package sacrificial layer; generating gas molecules from the package sacrificial layer by applying external stimuli such as light or heat to the package sacrificial layer; and heating the gas molecule and forming a cavity between the device and the package cap.

### CROSS REFERENCE TO RELATED APPLICATIONS

This application claims priority to South Korean Application No. 10-2014-0044469 filed Apr. 14, 2014, the contents of which are herein incorporated by reference in its entirety.

### BACKGROUND

1. Field

The embodiment may relate to a device packaging method and a device package using the same.

2. Description of Related Art

Recently, products are now being actively developed by applying micro-electro mechanical system (MEMS) technology which is advantageous for micro-miniaturization and high-precision. Various technologies for forming a MEMS device package including a fixed part which is fixed by various methods and an actuator which moves with respect to the fixed part are applied to the MEMS technology.

As examples of an apparatus including the MEMS device package, there are an accelerometer, a pressure sensor, a flow sensor, a transducer, micro-actuators, and the like. The apparatus including the MEMS device package is manufactured by a MEMS manufacturing technology including photolithography, thin film deposition, bulk micro-machining, surface micro-machining and etching, etc.

FIG. 1 is a cross sectional view of a general MEMS device package. Referring to FIG. 1, in a MEMS device package 1, a MEMS device 3 is disposed on a device wafer 2, and a package cap 4 surrounds the MEMS device 3. Since the MEMS device 3 operates mechanically within the package cap 4, a sufficient internal space 5 is required. For the purpose of forming the MEMS device package, a wafer bonding method and a thin film encapsulation (TFE) method are used.

FIG. 2A is a view for describing the wafer bonding method. As shown in FIG. 2A, pre-etched silicone (Si) or glass wafer is used as a cap. That is, the MEMS device is completed on the device wafer, and then is covered by bonding. In the wafer bonding, since the temperature of the bonding is very high and a separate space for bonding is required at the border of the MEMS device, the packaging size is very large. Also, the MEMS device is completed on the device wafer, and then is additionally covered by the cap. As a result, the completed MEMS device may be damaged during the packaging process. Further, the wafer of the cap is additionally required, and thus, cost is increased.

FIG. 2b is a view for describing the thin film encapsulation method. As shown in FIG. 2b, the packaging is performed during the MEMS device process. A sacrificial layer is disposed on the MEMS device and is deposited with a thin film, and then the inner sacrificial layer is removed. After that, a sealing layer is covered. Since this thin film encapsulation method does not include bonding, the problem caused by the bonding is solved. However, it takes much time to remove the sacrificial layer. Many tries have been made to reduce the time required for removing the sacrificial layer. However, the sacrificial layer is deposited on the internal MEMS device or gas generated by the removal of the sacrificial layer is not easy to emit to the outside, so that the thin film is damaged. Also, in order to fill specific gas like N₂ in the inside of the package after the removal of the sacrificial layer, the process environment itself is required to be formed with N₂ gas.

### SUMMARY

One embodiment is a device packaging method which includes forming a package sacrificial layer by applying a first material on a substrate on which a device has been formed (S10); forming a package cap by applying a second material on the package sacrificial layer (S20); generating gas molecules from the package sacrificial layer by applying external stimuli such as light or heat to the package sacrificial layer (S30); and heating the gas molecule and forming a cavity between the device and the package cap (S40).

The device packaging method may further include controlling the degree of response of the package sacrificial layer to the external stimuli such as light or heat by heating the package sacrificial layer (S11) between the step (S10) of forming the package sacrificial layer and the step (S20) of forming the package cap.

The step (S40) of forming the cavity may further include developing the package cap (S41).

The first material may generate gas by the external stimuli, and the second material may pass the external stimuli through the first material.

The first material may be a positive photoresist, and the second material may be a negative photoresist.

The external stimulus may include at least one of light, heat, vibration and pressure.

The forming the package sacrificial layer may include patterning at least one protrusion formed on a side of the package sacrificial layer. The forming the package cap may include patterning the package cap such that an end of the protrusion protrudes toward the side of the package cap. The device packaging method may further include forming a discharge hole by irradiating light to the protrusion, the discharge hole for discharging the package sacrificial layer and gas in the cavity, and removing the package sacrificial layer and gas through the discharge hole and sealing the discharge hole.

Another embodiment is a device package which includes a substrate; a device formed on the substrate; and a package cap formed to surround the device. A cavity is formed between the device and the package cap, and the cavity is formed in the form of a dome.

The device package may further include a package sacrificial layer which is applied on the device. The package sacrificial layer may generate gas by external stimuli and may adhere to the inside of the package cap.

The external stimulus may include at least one of light, heat, vibration and pressure.

The package cap may be hardened when light is irradiated or heat is applied to the package cap.

### BRIEF DESCRIPTION OF THE DRAWINGS

FIG. 1 is a cross sectional view of a general MEMS device package;

FIG. 2A is a view for describing the wafer bonding method;

FIG. 2B is a view for describing a thin film encapsulation method;

FIG. 3 is a flowchart showing a device packaging method according to an embodiment of the present invention;

FIG. 4 is a view showing a step S10 in the device packaging method;

FIG. 5 is a view showing a step S11 in the device packaging method;

FIG. 6 is a view showing a step S20 in the device packaging method;

FIG. 7 is a view showing a step S30 in the device packaging method;

FIG. 8 is a view showing a step S40 in the device packaging method;

FIG. 9 is a view showing a step S41 in the device packaging method;

FIG. 10 is a view showing a step S60 in the device packaging method;

FIG. 11 shows a result that a cavity formed by the device packaging method according to the embodiment of the present invention has been measured by a scanning electron microscope (SEM);

FIGS. 12A and 12B are views for describing the device packaging method according to the embodiment; and

FIGS. 13A, 13B, 13C and 13D are views for describing the device packaging method for vacuumizing the inside of the cavity or for filling the inside of the cavity with gas different from gas generated from a first material.

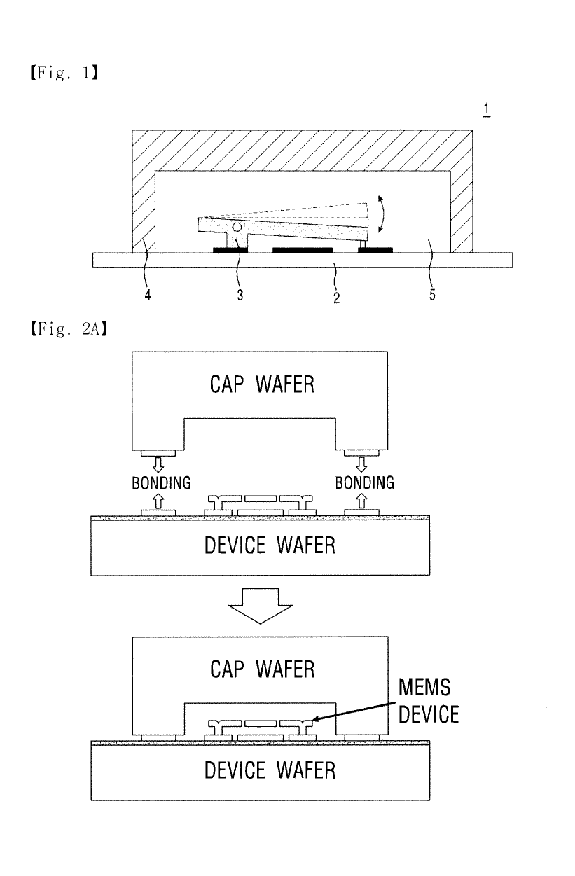

### DETAILED DESCRIPTION

The following detailed description of the present invention shows a specified embodiment of the present invention and will be provided with reference to the accompanying drawings. The embodiment will be described in enough detail that those skilled in the art are able to embody the present invention. It should be understood that various embodiments of the present invention are different from each other and need not be mutually exclusive. For example, a specific shape, structure and properties, which are described in this disclosure, may be implemented in other embodiments without departing from the spirit and scope of the present invention with respect to one embodiment. Also, it should be noted that positions or placements of individual components within each disclosed embodiment may be changed without departing from the spirit and scope of the present invention. Therefore, the following detailed description is not intended to be limited. If adequately described, the scope of the present invention is limited only by the appended claims of the present invention as well as all equivalents thereto. Similar reference numerals in the drawings designate the same or similar functions in many aspects.

Hereafter, a device packaging method will be described.

FIG. 3 is a flow chart showing a device packaging method according to an embodiment of the present invention.

Referring to FIG. 3, the device packaging method includes a step of forming a package sacrificial layer 300 by applying a first material on a substrate 100 on which a device (not shown) has been formed (S10), a step of forming a package cap 400 by applying a second material on the package sacrificial layer 300 (S20), a step of applying external stimuli such as light or heat to the package sacrificial layer and generating gas molecule from the package sacrificial layer 300 (S30), and a step of heating the gas molecule and forming a cavity 500 between the device and the package cap 400 (S40).

Meanwhile, between the step S10 of forming the package sacrificial layer and the step S20 of forming the package cap, a step S11 of controlling the degree of response of the package sacrificial layer 300 to the external stimuli such as light or heat by heating the package sacrificial layer 300 may be added. Specifically, the solvent of the first material and the moisture within the package sacrificial layer 300 are removed by heating the package sacrificial layer 300, so that the package sacrificial layer 300 can be prevented from excessively responding to the external stimuli.

Also, the step S40 of forming the cavity 500 between the device and the package cap 400 may further include a step S41 of developing the package cap 400.

Here, the external stimuli may include at least one of light, heat, vibration and pressure. Specifically, regarding the external stimuli, it is preferable that light is irradiated or heat is applied. However, the external stimuli are not limited to this. The external stimuli may include the vibration caused by external impact, the variation of internal pressure caused by external pressure change, or the like. Hereafter, the following description will focus on the light and heat in the embodiment.

FIG. 4 is a view showing the step S10 in the device packaging method.

As shown in FIGS. 3 and 4, in step S10, the package sacrificial layer 300 is formed in a packaging area by applying the first material on the substrate 100 on which the device (not shown) has been formed. Specifically, the first material may be applied on the substrate 100 to fully cover the device formed on the substrate 100. Since at least one device package is formed according to the packaging area on the substrate 100, a plurality of the package sacrificial layers 300, 301, 302 and 303 may be formed on the substrate 100. The first material may be polymer which generates particular gas when heated or exposed to light. Specifically, the first material may be a positive photoresist (PR) which is washed out by developing solution or may be a photoresist which generates particular gas when exposed to light. For example, the first material may be AZ 9260 photoresist which generates nitrogen molecules when exposed to light. The AZ 9260 photoresist may be applied on the substrate 100 by a spin coating method.

FIG. 5 is a view showing a step S11 in the device packaging method.

As shown in FIGS. 3 and 5, in Step S11, the package sacrificial layer 300 is heated. Specifically, the substrate on which the package sacrificial layer 300 has been formed is heated by a hot plate. For example, the substrate 100 may be heated at a temperature of from 80 to 120° C. for 8 to 12 minutes. Preferably, the substrate 100 may be heated at 100° C. for 10 minutes by the hot plate. When the package sacrificial layer 300 is heated, the solvent of the first material can be removed and excessive moisture within the package sacrificial layer 300 formed on the substrate 100 can be removed. Therefore, through the control of the moisture, it is possible to prevent the first material from excessively responding to external stimuli.

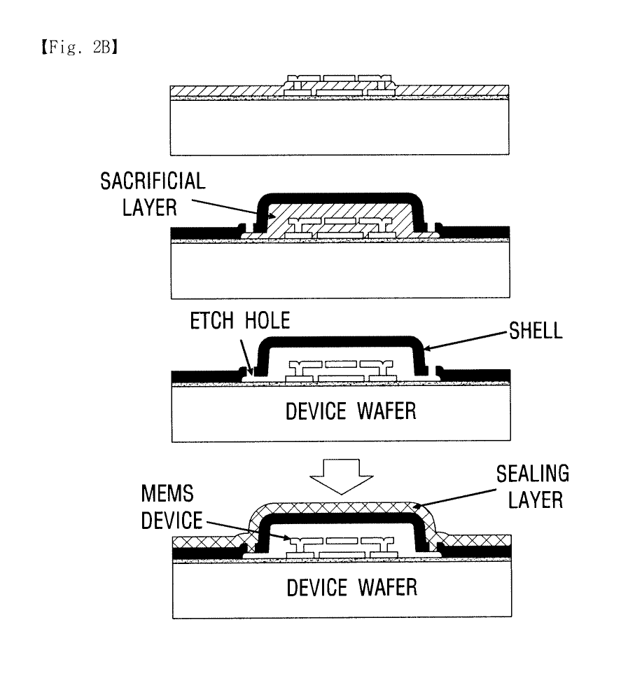

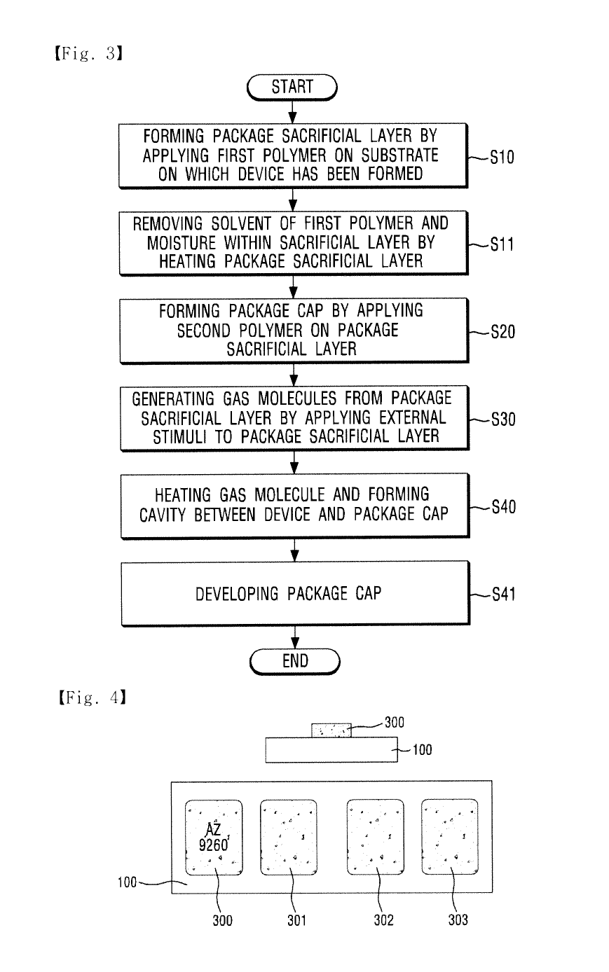

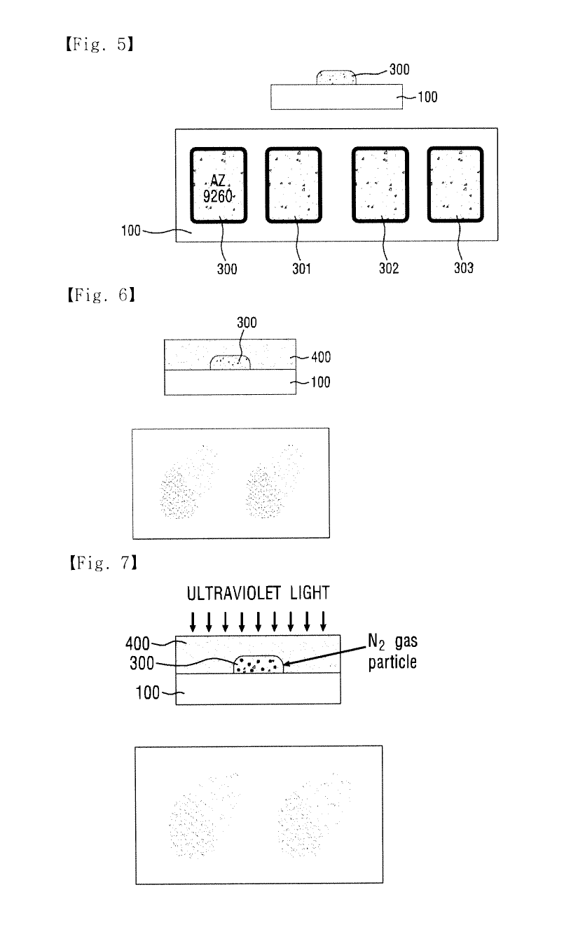

FIG. 6 is a view showing a step S20 in the device packaging method.

As shown in FIGS. 3 and 6, in step 20, the package cap 400 is formed by applying the second material on the package sacrificial layer 300 in such a manner as to cover the package sacrificial layer 300. The package cap 400 may be formed to fully cover even the side of the package sacrificial layer 300. Specifically, it is recommended that the package cap 400 fully covers such that the cavity 500 is formed within the package cap 400 through the process subsequent to step 20. The second material may not block the light irradiated from the outside or heat applied from the outside is transferred to the first material. Therefore, the first material responds to the light or heat and generates particular gas. Meanwhile, the second material may be a negative photoresist (PR) which is hardened by exposure to light and is not washed out by the developing solution. For example, the second material may be SU-8 photoresist. Therefore, when the second material is hardened, it is possible to more effectively prevent the gas generated from the first material from being flowed to the outside.

FIG. 7 is a view showing a step S30 in the device packaging method.

As shown in FIGS. 3 and 7, in step 30, the package sacrificial layer 300 and package cap 400 are exposed to the light or heat. The response of the photoresist can be effective obtained by using ultraviolet (UV) among lights. When the package sacrificial layer 300 and package cap 400 are exposed to the light or heat, the package sacrificial layer 300 generates gas molecules and the package cap 400 may not respond to the light or heat or may be hardened. Therefore, the gas molecules generated from the package sacrificial layer 300 exposed to the light or heat are not diffused to the outside due to the package cap 400 and is confined within the package cap 400.

FIGS. 8 to 10 are views showing a step S40 in the device packaging method.

As shown in FIGS. 3 and 8, in step 40, the package sacrificial layer 300 and package cap 400 are heated. When the package sacrificial layer 300 is heated, the gas molecules confined within the package sacrificial layer 300 receive thermal energy and form bubbles in the form of gas. Specifically, when the package sacrificial layer 300 is heated at a temperature higher than 30° C., micro bubbles begin to appear. When the package sacrificial layer 300 is heated to 150° C., the micro bubbles gather and form huge bubbles. Here, since nitrogen bubbles attempt to go outside the package sacrificial layer 300, the nitrogen bubbles gather at the interface which is formed between the package sacrificial layer 300 and the substrate 100 and has a relatively low adhesive strength rather than the interface which is between the package sacrificial layer 300 and the package cap 400 and has a relatively high adhesive strength.

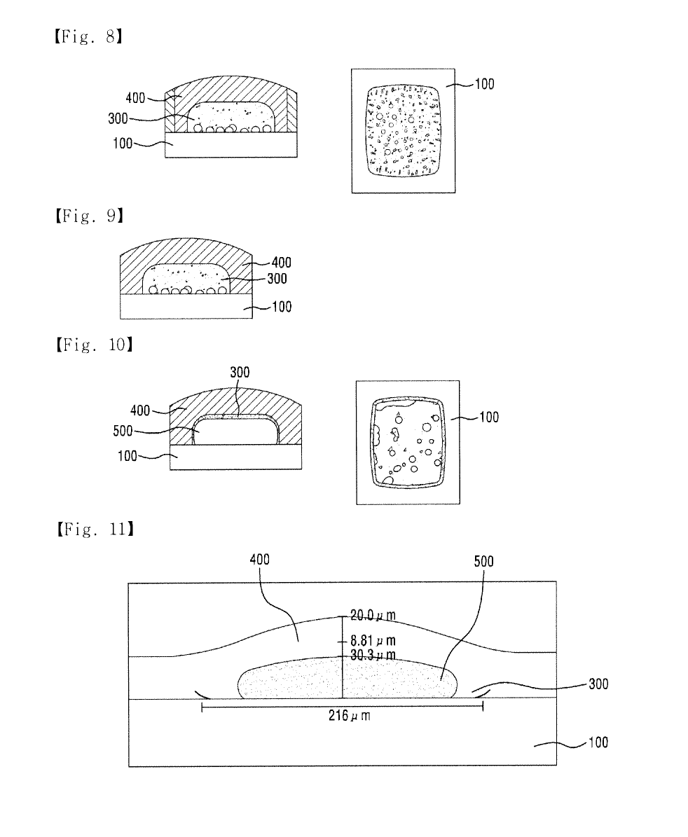

As shown in FIGS. 3 and 9, the package cap 400 of the device package, in which the bubbles have been formed, may be developed (S41). Accordingly, in the package cap 400 comprised of the negative photoresist, the portion of the package cap 400, which is not exposed to light, is washed out and removed by the developing solution. The step S41 of developing the package cap 400 may be performed after the cavity 500 is formed or may be performed from a time after the bubbles are formed to a time before the cavity 500 is formed.

As shown in FIG. 10, the heat is continuously applied to the package sacrificial layer 300 and package cap 400 from which the bubbles have been formed. Specifically, the package sacrificial layer 300 and package cap 400 may be heated at a temperature of from 130 to 170 for 8 to 12 minutes by the hot plate. Preferably, it is recommended that the package sacrificial layer 300 and package cap 400 are heated at 150° C. for 10 minutes. When the package sacrificial layer 300 is heated, the already formed nitrogen bubbles grow bigger and bigger and combine with each other, forming an enormous cluster shape, and then the package sacrificial layer 300 is changed into a liquid form. Also, when the heat is applied to the package cap 400, the package cap 400 may be more firmly hardened. Accordingly, the liquefied package sacrificial layer 300 becomes farther from the substrate by the nitrogen gas located at the interface between the substrate 100 and the package sacrificial layer 300 and relatively uniformly adheres to the interface between the package cap 400 and the package sacrificial layer 300. Therefore, the dome-shaped cavity 500 is formed within the package cap 400 and is filled with the gas.

FIG. 11 shows a result that a cavity formed by the device packaging method according to the embodiment of the present invention has been measured by a scanning electron microscope (SEM).

As shown in FIG. 11, when the package sacrificial layer 300 is comprised of 10 μm-thick AZ 9260 photoresist and the package cap 400 is comprised of 20 μm-thick SU-8 photoresist, it can be understood that the cavity 500 is formed to have the dome shape and the maximum height of the cavity 500 from the substrate 100 is 30. 3 μm. Therefore, the 10 μm-thick package sacrificial layer 300 adheres to the inside of the package cap 400 while passing through the process according to the embodiment, and the dome-shaped cavity 500 having the maximum height of 30 μm is formed within the package cap 400.

Accordingly, the device packaging method according to the embodiment does not require the following process used in the thin film encapsulation (TFE) method. The process used in the thin film encapsulation (TFE) method is performed by forming a hole in the cap so as to form the cavity and by injecting etchant into the hole to remove the inner sacrificial layer. Therefore, subsequent sealing process or passivation process is also not required, so that the process step can be reduced. Also, since SU-8 photoresist used in the package cap is sufficiently applied, the package cap is resistant to external impact and pressure. Also, since the package sacrificial layer is exposed to light and generates nitrogen gas, there is no requirement for a process or process environment for filling the inside of the cavity with the nitrogen gas. The inside of the cavity is formed to have the dome shape. Accordingly, even when a large area is packaged, the device packaging method according to the embodiment has higher stability against the external pressure than that of an existing packaging method having a rectangular cap. Since the first material constituting the package sacrificial layer and the second material constituting the package cap are applied by the spin coating method, coating can be easily performed and the cavity can be simply and quickly formed.

Hereafter, the method of packaging the device disposed within the cavity will be described.

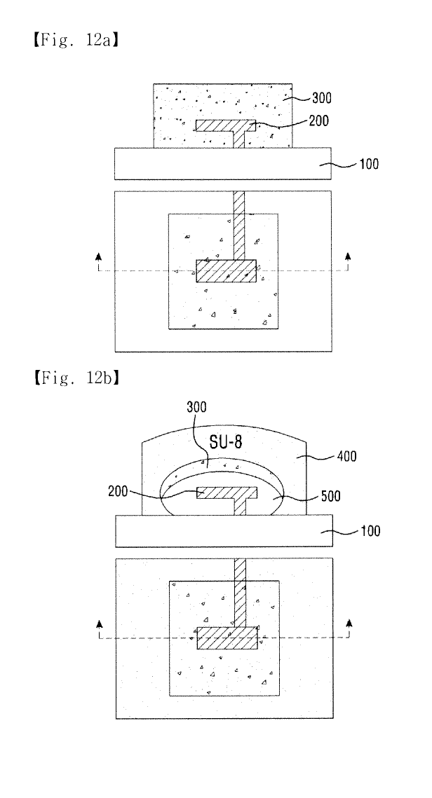

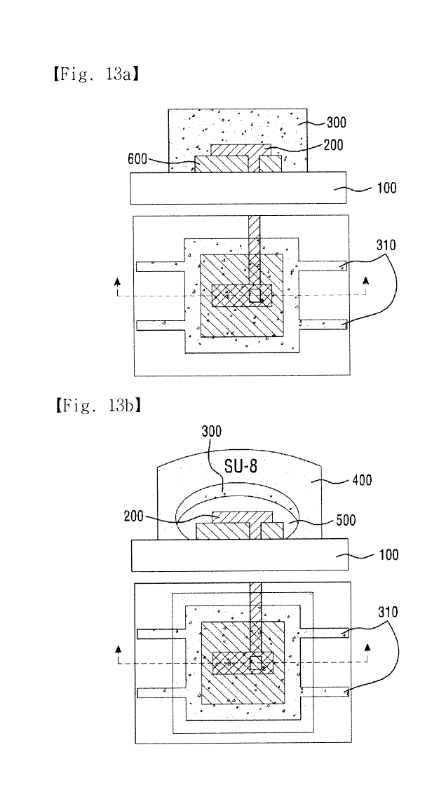

FIGS. 12A and 12B are views for describing the device packaging method according to the embodiment.

Referring to FIG. 12A, a device 200 is formed on the substrate 100, and a device sacrificial layer is removed. Since the process of forming the device 200 on the substrate 100 has been widely known, the detailed description of the process will be omitted. The process of forming the device 200 on the substrate 100 is not specifically limited, and the device 200 may be formed on the substrate 100 by any process.

The device 200 may be the MEMS device. However, the device 200 is not limited to the MEMS device. Any device will be accepted so long as it can be formed on the substrate.

As shown in FIG. 12A, the package sacrificial layer 300 is formed on the device 200 by using the positive photoresist.

Referring to FIG. 12B, the package cap 400 is applied to cover the entire package sacrificial layer 300, and then the package sacrificial layer 300 and the package cap 400 are exposed to light, developed and heated. The package sacrificial layer 300 is exposed to light to generate gas molecules and is liquefied by being heated. Here, the generated gas molecules become bubbles, form clusters and cause the liquefied package sacrificial layer 300 to adhere to the package cap 400. As a result, the dome-shaped cavity 500 is formed. The package cap 400 is exposed to light and hardened. The portion of the package cap 400, which is not exposed to light, is removed by the developing solution. When the package cap 400 is heated, the package cap 400 is further hardened.

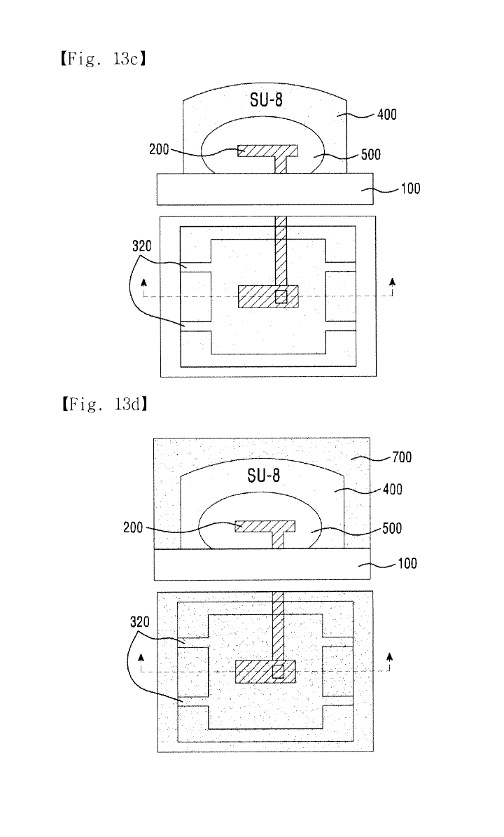

FIGS. 13A to 13D are views for describing the device packaging method for vacuumizing the inside of the cavity or for filling the inside of the cavity with gas different from gas generated from a first material.

Referring to FIG. 13A, the device 200 is formed on the substrate 100 and the device sacrificial layer has not been removed. The device sacrificial layer 600 is made of the positive photoresist. Therefore, as will be described below, the device sacrificial layer 600 is liquefied by exposure to light and is removed to the outside.

As shown in FIG. 13A, the package sacrificial layer 300 is formed on the device 200 by using the positive photoresist. Here, the positive photoresist is patterned such that a protrusion 310 for forming a discharge hole 320 is formed on the side of the package sacrificial layer 300.

Referring to FIG. 13B, the package cap 400 is applied to cover the package sacrificial layer 300. Here, the package cap 400 is patterned such that an end of the protrusion 310 protrudes toward the side of the package cap 400. The package sacrificial layer 300 and the package cap 400 are exposed to light, developed and heated. The package sacrificial layer 300 is exposed to light to generate gas molecules and is liquefied by being heated, Here, the generated gas molecules become bubbles, form clusters and cause the liquefied package sacrificial layer 300 to adhere to the package cap 400. As a result, the dome-shaped cavity 500 is formed. The package cap 400 is exposed to light and hardened. The portion of the package cap 400, which is not exposed to light, is removed by the developing solution. When the package cap 400 is heated, the package cap 400 is further hardened.

Referring to FIG. 13C, the protrusion 310 formed on the side of the package sacrificial layer 300 is made of the positive photoresist. Accordingly, when the light is irradiated to the protrusion 310, the protrusion 310 is liquefied and is removed by the developing solution. Therefore, the discharge hole 320 is formed in the position where the protrusion 310 made of the first material has been removed. The discharge hole 320 according to the embodiment may be narrow and long. The liquefied package sacrificial layer 300, gas and liquefied device sacrificial layer 600 in the cavity 500 can be removed through the discharge hole 320.

Referring to FIG. 13D, when the operation of FIG. 13D is performed in a vacuum environment or in a desired gas environment, it is possible to vacuumize the inside of the cavity 500 or to fill the inside of the cavity 500 with the desired gas. By blocking the discharge hole 320 by means of a sealing material 700, the inside of the cavity 500 becomes a vacuum state or is filled with the desired gas. Here, since the discharge hole 320 is narrow and long, the sealing material does not penetrate to where the inner device is located.

As described above, the cavity may be formed to have the dome shape by using the device packaging method according to the embodiment of the present invention. Therefore, even though the cavity is in a vacuum state, it is possible to prevent that the internal space of the cavity is damaged by a pressure difference between the inside and the outside of the cavity. Compared with the thin film encapsulation (TFE) method which is performed by forming a hole in the cap so as to form the inner cavity and by injecting etchant into the hole to remove the inner sacrificial layer, the device packaging method according to the embodiment of the present invention has no necessity to form a hole in the cap and fills the cavity with nitrogen gas without sealing. Accordingly, the manufacturing process can be significantly reduced. Also, the nitrogen gas is clustered and then the cavity is formed to have the dome shape. Accordingly, even when a large area is packaged, the device packaging method according to the embodiment has higher stability against the external pressure than that of an existing packaging method having a flat cap. In particular, also regarding a vacuum package which is formed by sealing in a vacuum state, it is possible to obtain high stability by using the dome-shaped cavity structure despite the absence of the gas within the cavity. Since the external pressure manufacturing process is performed only by applying polymer and irradiating light through use of the spin coating method, packaging can be performed very simply and rapidly. The device package formed by such a packaging method allows the negative photoresist constituting the package cap to be thickly applied, and thus is resistant to external impact and pressure.

A MEMS device package formed by the device packaging method according to the above-described embodiment will be described.

Referring to FIGS. 12B and 13D, the MEMS device package according to the embodiment includes the substrate 100, the MEMS device 200 which is formed on the substrate 100, and the package cap 400 which surrounds the MEMS device 200. The cavity 500 may be formed between the MEMS device 200 and the package cap 400 in the form of a dome. Therefore, the upper portion of the cavity 500 may be formed in the form of an arch, and the inside of the package cap 400 may be formed corresponding to the arch-shaped upper portion of the cavity 500. Although the package sacrificial layer 300 generated during the manufacturing process may adhere to the lower surface of the inside of the package cap 400 and the upper surface of the cavity 500, the package sacrificial layer 300 can be removed through the above-described discharge hole 320.

As shown in FIGS. 12B and 13D, the substrate 100 may be a silicon (Si) substrate. Specifically, the substrate 100 may be a semiconductor wafer.

The MEMS device 200 may be formed on the substrate 100. The MEMS device 200 may be one of various MEMS devices, such as an RF device.

The package cap 400 is formed to surround the MEMS device 200. The package cap 400 is formed outside the MEMS device 200, and the cavity 500 is formed between the MEMS device 200 and the package cap 400 so as to mechanically drive the MEMS device 200. The package cap 400 may be made of polymer. Specifically, the package sacrificial layer 300 made of a first polymer may adhere to the inside of the package cap 400, and the package cap 400 may be made of a second polymer. For example, the first polymer may be the positive photoresist, and specifically, may be AZ 9260 photoresist which generates nitrogen gas when exposed to ultraviolet light. The second polymer may transmit the ultraviolet light therethrough. For example, the second polymer may be the negative photoresist which is hardened by exposure to ultraviolet light, and specifically may be SU-8 photoresist.

The cavity 500 may be formed between the MEMS device 200 and the package cap 400 in the form of a dome, The inside of the cavity 500 may be in a vacuum state or may be filled with particular gas. For example, nitrogen gas N₂ which has a low degree of response to the MEMS device may be filled in the cavity 500. The nitrogen gas is filled in the cavity 500, thereby preventing contamination caused by the contact between the MEMS device 200 and the inside of the package cap 400 when the MEMS device 200 is driven. Also, as described above, the cavity 500 may be filled with another gas other than nitrogen gas or may be in a vacuum state.

Therefore, the cavity 500 is formed to have the dome shape and the upper portion of the cavity 500 is formed in the form of an arch, so that the MEMS device package 10 according to the embodiment is resistant to the external pressure.

The features, structures and effects and the like described in the embodiments are included in at least one embodiment of the present invention and are not necessarily limited to one embodiment. Furthermore, the features, structures, effects and the like provided in each embodiment can be combined or modified in other embodiments by those skilled in the art to which the embodiments belong. Therefore, contents related to the combination and modification should be construed to be included in the scope of the present invention.

Although embodiments of the present invention were described above, these are just examples and do not limit the present invention. Further, the present invention may be changed and modified in various ways, without departing from the essential features of the present invention, by those skilled in the art. For example, the components described in detail in the embodiments of the present invention may be modified. Further, differences due to the modification and application should be construed as being included in the scope and spirit of the present invention, which is described in the accompanying claims.

What is claimed is:

1. A device packaging method comprising:
forming a package sacrificial layer by applying a first material on a substrate on which a device has been formed (S 10);
forming a package cap by applying a second material on the package sacrificial layer (S20);
generating gas molecules from the package sacrificial layer by applying external stimuli such as light or heat to the package sacrificial layer (S30); and
heating the gas molecule and forming a cavity between the device and the package cap (S40).

2. The device packaging method of claim 1, further comprising controlling the degree of response of the package sacrificial layer to the external stimuli such as light or heat by heating the package sacrificial layer (S11) between the step (S10) of forming the package sacrificial layer and the step (S20) of forming the package cap.

3. The device packaging method of claim 1, wherein the step (S40) of forming the cavity further comprises developing the package cap (S41).

4. The device packaging method of claim 1, wherein the first material generates gas by the external stimuli, and wherein the second material passes the external stimuli through the first material.

5. The device packaging method of claim 2, wherein the first material generates gas by the external stimuli, and wherein the second material passes the external stimuli through the first material.

6. The device packaging method of claim 3, wherein the first material generates gas by the external stimuli, and wherein the second material passes the external stimuli through the first material.

7. The device packaging method of claim 4, wherein the first material is a positive photoresist, and wherein the second material is a negative photoresist.

8. The device packaging method of claim 5, wherein the first material is a positive photoresist, and wherein the second material is a negative photoresist.

9. The device packaging method of claim 6, wherein the first material is a positive photoresist, and wherein the second material is a negative photoresist.

10. The device packaging method of claim 4, wherein the external stimulus comprises at least one of light, heat, vibration and pressure.

11. The device packaging method of claim 5, wherein the external stimulus comprises at least one of light, heat, vibration and pressure.

12. The device packaging method of claim 6, wherein the external stimulus comprises at least one of light, heat, vibration and pressure.

13. The device packaging method of claim 1, wherein the forming the package sacrificial layer comprises patterning at least one protrusion formed on a side of the package sacrificial layer, and wherein the forming the package cap comprises patterning the package cap such that an end of the protrusion protrudes toward the side of the package cap,
further comprising:
forming a discharge hole by irradiating light to the protrusion, the discharge hole for discharging the package sacrificial layer and gas in the cavity, and
removing the package sacrificial layer and gas through the discharge hole and sealing the discharge hole.

14. A device package comprising:
a substrate;
a device formed on the substrate; and
a package cap formed to surround the device,
wherein a cavity is formed between the device and the package cap, and the cavity is formed in the form of a dome.

15. The device package of claim 14, further comprising a package sacrificial layer which is applied on the device, wherein the package sacrificial layer generates gas by external stimuli and adheres to the inside of the package cap.

16. The device package of claim 15, wherein the external stimulus comprises at least one of light, heat, vibration and pressure.

17. The device package of claim 15, wherein the package cap is hardened when light is irradiated or heat is applied to the package cap.
